(19) United States
(12) Patent Application Publication
(10) Pub. No.: US 2025/0096139 A1
(43) Pub. Date: Mar. 20, 2025

(54) AIRGAPS IN TOP LAYERS OF SEMICONDUCTOR DEVICES

(71) Applicant: QUALCOMM Incorporated, San Diego, CA (US)

(72) Inventors: John Jianhong ZHU, San Diego, CA (US); Junjing BAO, San Diego, CA (US); Giridhar NALLAPATI, San Diego, CA (US)

(21) Appl. No.: 18/468,366

(22) Filed: Sep. 15, 2023

(51) Int. Cl. H01L 23/532; H01L 21/768; H01L 23/522; H01L 23/528

(52) U.S. Cl. CPC H01L 23/53209; H01L 21/7682; H01L 21/76877; H01L 23/5222; H01L 23/5283

(57) ABSTRACT

Disclosed are devices that may incorporate airgaps in top signal layers and/or power layers on a frontside of a substrate. Alternatively, or in addition thereto, airgaps may also be incorporated in signal layers and/or power layers on a backside of the substrate. In this way, metal capacitances of the devices may be reduced, which thereby improves performance of semiconductor circuits such as CPUs.

### FIELD OF DISCLOSURE

This disclosure relates generally to semiconductor devices, and more specifically, but not exclusively, to providing airgaps in layers, such as in top (or frontside) signal and/or power layers, of semiconductor devices, e.g., for improving CPU performances, and fabrication techniques thereof.

### BACKGROUND

Integrated circuit (IC) technology has achieved great strides in advancing computing power through miniaturization of active components. Higher frequency has been continuously targeted, e.g., in (central processing unit) CPU designs, by an explosion in calculation demand. With continually scaling of such devices, metal capacitance is becoming a key parameter for both performance and power. Metal capacitance has a large contribution to delay. For high performance CPU or cores, long signal wires are widely used in top layers, which are usually thick. Hence, top layer metal capacitance can be a significant contributor (e.g., as much as 30% or more) to the capacitance of back end-of-line (BEOL) capacitances.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary device is disclosed. The device may comprise a substrate. The device may also comprise a semiconductor circuit on a frontside of the substrate. The device may further comprise one or more frontside metal layers on the semiconductor circuit on the frontside of the substrate. The device may yet comprise one or more frontside signal layers on the one or more frontside metal layers on the frontside of the substrate. The one or more frontside signal layers may be configured to carry one or more signals to and/or from the semiconductor circuit. The one or more frontside signal layer may comprise a first frontside signal layer. The first frontside signal layer may comprise one or more top signal metals including a first top signal metal. A frontside airgap may be formed on a side surface of the first top signal metal.

A method of fabricating a device is disclosed. The method may comprise providing a substrate. The method may also comprise providing a semiconductor circuit on a frontside of the substrate. The method may further comprise forming one or more frontside metal layers on the semiconductor circuit on the frontside of the substrate. The method may yet comprise forming one or more frontside signal layers on the one or more frontside metal layers on the frontside of the substrate. The one or more frontside signal layers may be configured to carry one or more signals to and/or from the semiconductor circuit. The one or more frontside signal layer may comprise a first frontside signal layer. The first frontside signal layer may comprise one or more top signal metals including a first top signal metal. A frontside airgap may be formed on a side surface of the first top signal metal.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates views of devices with airgaps in stacked metal layers in accordance with one or more aspects of the disclosure.

FIGS. 2, 3 and 4 illustrate embodiments of metal layers of devices with airgaps in accordance with one or more aspects of the disclosure.

FIG. 5A-5E, 6A-6F and 7A-7F illustrate various stages of fabricating the metal layers of devices with airgaps in accordance with one or more aspects of the disclosure.

FIG. 8 illustrates a top view of a device with airgaps in stacked metal layers in accordance with one or more aspects of the present disclosure.

FIGS. 9-11 illustrate flow charts of example methods of fabricating metal layers of devices with airgaps in accordance with one or more aspects of the disclosure.

FIG. 12 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As indicated above, metal capacitance is becoming a key parameter for both performance and power in devices. Metal capacitance has a large contribution to delay. For high performance CPU or cores, long signal wires are widely used in top layers, which are usually thick. Hence, top layer metal capacitance can be a significant contributor (e.g., as much as 30% or more) to the capacitance of back end-of-line (BEOL) capacitances.

To address these and other issues of conventional devices, it is proposed to provide airgaps in signal wires. In particular, it is proposed to provide airgaps in top thick signal lines. Since air has very low k value, metal capacitances can be significantly reduced. Due to the metal capacitance reduction, CPU performance can be correspondingly improved, especially when the airgaps are used next to critical paths. If both front and backsides of a substrate is used, then airgaps may be incorporated in critical signal paths on the frontside and/or the backside.

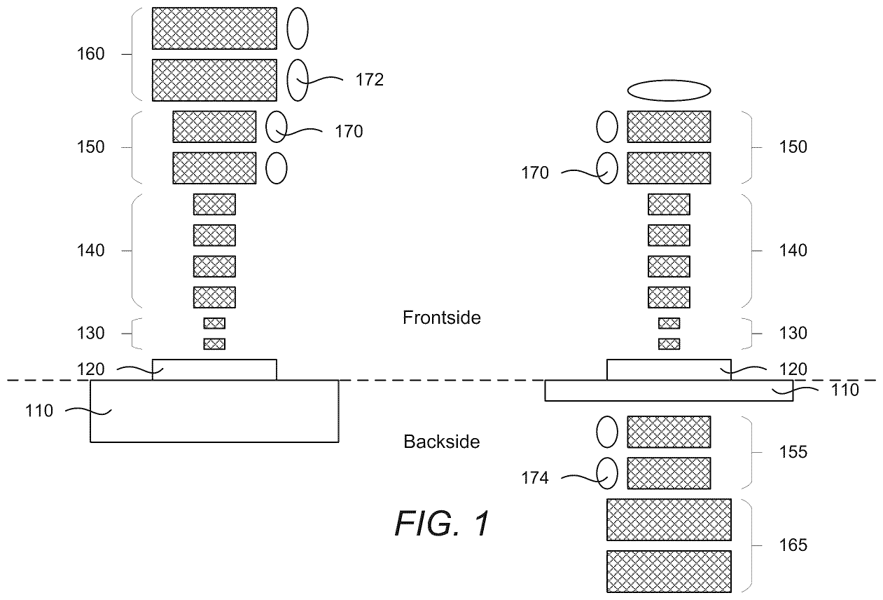

FIG. 1 illustrates views of devices with airgaps in stacked metal layers in accordance with one or more aspects of the disclosure. The stacked structure on the left illustrates a situation where the metal layers are stacked only on the frontside. For ease of reference, this structure may be referred to as frontside-only stacked structure. As seen, the frontside-only stacked structure may include a substrate (e.g., silicon (Si) substrate) 110 and a semiconductor circuit 120 on the frontside of the substrate 110. The semiconductor circuit 120 may be formed as a result of front end-of-line (FEOL) and middle-of-line (MOL) processes. One or more frontside lower metal layers 130 may be on the semiconductor circuit 120 on the frontside of the substrate 110. Then one or more frontside intermediate metal layers 140 may be on the frontside lower metal layers 130. The frontside intermediate metal layers 140 may be thicker than the frontside lower metal layers 130. More generally, metals of the frontside intermediate metal layers 140 may have greater cross sections than metals of the frontside lower metal layers 130. The frontside lower metal layer 130 and the frontside intermediate metal layer 140, individually or in combination, may also generally be referred to as frontside metal layers.

One or more frontside signal layers 150 may be formed on the frontside intermediate metal layers 140 on the frontside of the substrate 110. It should be noted that it is NOT strictly necessary that there be both the frontside lower metal layers 130 and the frontside intermediate metal layers 140. Also, there can be other metal layers in between frontside intermediate metal layers 140 and the frontside signal layers 150. In an aspect, it is contemplated that there are one or more frontside metal layers (e.g., the frontside lower metal layer 130 and/or the frontside intermediate metal layer 140) in between semiconductor circuit 120 and the frontside signal layers 150. The frontside signal layers 150 may be the top signal layers of the device that carry signals to and/or from the semiconductor circuit 120. Metals of the frontside signal layers 150 may be thicker than any metals of the frontside metal layers including the metals of the frontside lower metal layers 130 and of the frontside intermediate metal layers 140. More generally, metals of the frontside signal layers 150 may have greater cross sections than metals of the frontside metal layers 130, 140.

Airgaps 170 may be formed in one or both of the frontside signal layers 150. For ease of reference, the airgaps 170 may be referred to as frontside airgaps 170. As will be shown below, the frontside airgaps 170 may be formed on side surfaces of the top signal metals, which may be metals of the frontside signal layers 150. When there are multiple frontside airgaps 170, one may be referred to as a first frontside airgap, another may be referred to as a second frontside airgap, and so on. Note that frontside airgaps 170 may be formed in at least two consecutive frontside signal layers 150.

The frontside-only stacked metal structure may include one or more frontside power layers 160 on the one or more frontside signal layers 150 on the frontside of the substrate 110. The one or more frontside power layers 160, which may also be referred to as top power layers 160, may be configured to carry power to the semiconductor circuit 120. In an aspect, the metals of the frontside power layers 160 may have greater cross sections than the top signal metals of the frontside signal layers 150.

Some critical paths can be designed in the top (frontside) power layers 160. To improve the performance of such critical paths, it may be desirable to build airgap(s) surrounding such paths in the frontside power layers 160. Airgaps 172 may be formed in one or both of the frontside power layers 160. For ease of reference, the airgaps 172 may be referred to as frontside power airgaps 172. As will be shown below, the frontside power airgaps 172 may be formed on side surfaces of the frontside power metals, which are metals of the frontside power layers 160. When there are multiple frontside power airgaps 172, one may be referred to as a first frontside power airgap, another may be referred to as a second frontside power airgap 172, and so on. Note that frontside power airgaps 172 may be formed in at least two consecutive frontside power layers 160.

The stacked structure on the right of FIG. 1 illustrates a situation where the metal layers are stacked on both front and backside. For ease of reference, this structure may be referred to as frontside/backside stacked structure. As seen, the frontside/backside stacked structure may include a substrate 110, a semiconductor circuit 120 on the frontside of the substrate 110, and one or more frontside metal layers (e.g., frontside lower metal layers 130, frontside intermediate metal layers 140, etc.). These are similar to the substrate 110, the semiconductor circuit 120, and the frontside metal layers (e.g., frontside lower metal layers 130, frontside intermediate metal layers 140, etc.) discussed above with respect to the frontside-only stacked structure. Thus, a detailed description thereof will be omitted for sake of brevity.

The frontside/backside stacked structure may also include one or more frontside signal layers 150 formed on the frontside metal layers on the frontside of the substrate 110. However, unlike the frontside-only stacked structure, there need not be any frontside power layers. That is, in an aspect, the one or more frontside signal layers 150 may be the top layers of the frontside/backside stacked structure. As such, an airgap 170 above the uppermost frontside signal layer 150 may also be formed (referred to as augmented airgap shown further below).

On the backside of the substrate, the frontside/backside stacked structure may include one or more backside signal layers 155. The backside signal layers 155 may be configured to carry signals to and/or from the semiconductor circuit 120. Metals of the backside signal layers 155 may be thicker than any metals of the frontside metal layers (e.g., the metals of the frontside lower metal layers 130, the metals of the frontside intermediate metal layers 140, etc.). More generally, metals of the backside signal layers 155 may have greater cross sections than metals of the frontside metal layers.

Airgaps 174 may be formed in one or both of the backside signal layers 155. For ease of reference, the airgaps 174 may be referred to as backside airgaps 174. As will be demonstrated below, the backside airgaps 174 may be formed on side surfaces of the backside signal metals, which may be metals of the backside signal layers 155. When there are multiple backside airgaps 174, one may be referred to as a first backside airgap, another may be referred to as a second backside airgap, and so on. Note that backside airgaps 174 may be formed in at least two consecutive backside signal layers 155.

The frontside/backside stacked metal structure may include one or more backside power layers 165 on the one or more backside signal layers 155 on the backside of the substrate 110. The one or more backside power layers 165 may be configured to carry power to the semiconductor circuit 120. In an aspect, the metals of the backside power layers 165 may have greater cross sections than the signal metals of the backside signal layers 155.

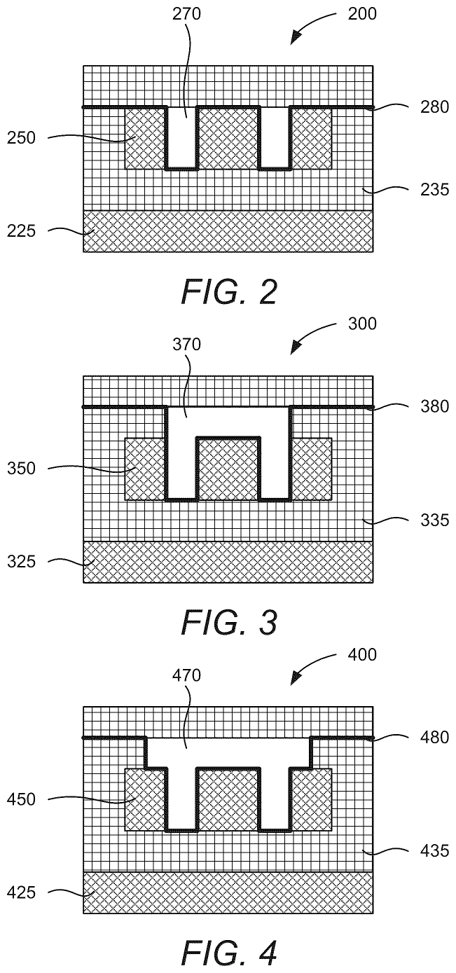

FIG. 2 illustrates a cross-section of metal layers of a device 200. As seen, the device 200 may include a previous metal layer 225, a dielectric 235 formed on the previous metal layer 225, one or more metals 250 of a metal layer within the dielectric 235, airgaps 270 between adjacent metals 250, and a protection layer 280 formed on upper surfaces of the metals 250, on side surfaces of the metals 250 and dielectric 235 exposed by the airgap 270. In an aspect, the dielectric 235 may be formed from silicon dioxide (SiO₂) and or a low-k dielectric. The protection layer 280 may be formed from a polymer (such as polycyclohexyl methacrylate (PCHMA)), tantalum nitride (TaN), titanium nitride (TiN) thin film, etc.

In an aspect, FIG. 2 may correspond to layers of the frontside signal layers 150. In this instance, assume that FIG. 2 corresponds with a first frontside signal layer 150 (one of the one or more frontside signal layers 150). Then the metals 250 may be viewed as top signal metals of the first frontside signal layer 150. Also assume that the middle metal 250 is a first top signal metal, and airgaps 270 correspond to frontside airgaps 170. In this instance, it may be said that the frontside airgap 170 is formed at least on a side surface of the first top signal metal. It also may be said that the first top signal metal has a larger cross section than any metal of the frontside metal layers 130, 140. Note that there are airgaps 270 formed on both side surfaces of the middle metal 250. That is, another frontside airgap 170 may be formed on another side surface of the first top signal metal.

Referring back to FIG. 1, note that there can be multiple frontside airgaps 170 in different frontside signal layers 150. Then the airgap 270 of FIG. 2 may be a first frontside airgap 170. When there are multiple frontside signal layers 150, there may be a second frontside signal layer 150 immediately above or below the first frontside signal layer 150. Then there may be second frontside airgap 170 formed on a side surface of at least one signal metal 250 of the second frontside signal layer 150.

In an aspect, FIG. 2 may also correspond to layers of the backside signal layers 155. In this instance, assume that FIG. 2 corresponds with a first backside signal layer 155 (one of the one or more backside signal layers 155). Then the metals 250 may be viewed as backside signal metals of the first backside signal layer 155. Also assume that the middle metal 250 is a first backside signal metal, and airgaps 270 correspond to backside airgaps 174. In this instance, it may be said that the backside airgap 174 is formed at least on a side surface of the first backside signal metal. It also may be said that the first backside signal metal has a larger cross section than any metal of the frontside metal layers 130, 140. Note that there are airgaps 270 formed on both side surfaces of the middle metal 250. That is, another backside airgap 174 may be formed on another side surface of the first backside signal metal.

Referring back to FIG. 1, note that there can be multiple backside airgaps 174 in different backside signal layers 155. Then the airgap 270 of FIG. 2 may be a first backside airgap 174. When there are multiple backside signal layers 155, there may be a second backside signal layer 155 immediately above or below the first backside signal layer 155. Then there may be second backside airgap 174 formed on a side surface of at least one signal metal 250 of the second backside signal layer 155.

In an aspect, FIG. 2 may further correspond to layers of the frontside power layers 160. In this instance, assume that FIG. 2 corresponds with a first frontside power layer 160 (one of the one or more frontside power layers 160). Then the metals 250 may be viewed as frontside power metals of the first frontside power layer 160. Also assume that the middle metal 250 is a first frontside power metal, and airgaps 270 correspond to frontside power airgaps 172. In this instance, it may be said that the frontside power airgap 172 is formed at least on a side surface of the first frontside power metal. It also may be said that the first frontside power metal has a larger cross section than any metal of the frontside signal layers 150. Note that there are airgaps 270 formed on both side surfaces middle metal 250. That is, another frontside power airgap 172 may be formed on another side surface of the first frontside power metal.

Referring back to FIG. 1, note that there can be multiple frontside power airgaps 172 in different frontside power layers 160. Then the airgap 270 of FIG. 2 may be a first frontside power airgap 172. When there are multiple frontside power layers 160, there may be a second frontside power layer 160 immediately above or below the first frontside power layer 160. Then there may be second frontside power airgap 172 formed on a side surface of at least one signal metal 250 of the second frontside power layer 160.

FIG. 3 illustrates a cross-section of metal layers of a device 300. As seen, the device 300 may include a previous metal layer 325, a dielectric 335 formed on the previous metal layer 325, one or more metals 350 of a metal layer within the dielectric 335, an airgap 370 between adjacent metals 350, and a protection layer 380 formed on upper surfaces of the metals 350, on side surfaces of the metals 350 and dielectric 335 exposed by the airgap 370. In an aspect, the dielectric 335 may be formed from silicon dioxide (SiO₂) and or a low-k dielectric. The protection layer 380 may be formed from a polymer such as PCHMA.

In an aspect, FIG. 3 may correspond to a first frontside signal layer 150 (one of the one or more frontside signal layers 150). In this instance, the first frontside signal layer 150 may be the uppermost frontside signal layer 150 of the frontside/backside stacked structure of FIG. 1, in which the frontside airgap 170 may be an augmented airgap. That is, the airgap 370 of FIG. 3 may be an augmented airgap. Then the metals 350 may be viewed as top signal metals of the first frontside signal layer 150. Also assume that the middle metal 350 is a first top signal metal. The augmented airgap 370 may comprise at least one side portion (in this instance, two side portions are shown) and an upper lateral portion. The at least one side portion may be formed on side surface(s) of the first top signal metal 350. The upper lateral portion may be formed on an upper surface of the first top signal metal. Since there is another side portion, it may be said that the augmented airgap 370 comprises another side portion formed on another side surface of the first top signal metal 350.

FIG. 4 illustrates a cross-section of metal layers of a device 400. That is, the device 400 may include a previous metal layer 425, a dielectric 435 formed on the previous metal layer 425, one or more metals 450 of a metal layer within the dielectric 435, an airgap 470 between adjacent metals 450, and a protection layer 480 formed on upper surfaces of the metals 450, on side surfaces of the metals 450 and dielectric 435 exposed by the airgap 470. In an aspect, the dielectric 435 may be formed from silicon dioxide (SiO₂) and or a low-k dielectric. The protection layer 480 may be formed from a polymer such as PCHMA.

In an aspect, FIG. 4 may correspond to a first frontside signal layer 150 (one of the one or more frontside signal layers 150). In this instance, similar to device 300 of FIG. 3, the first frontside signal layer 150 may be uppermost frontside signal layers 150 of the frontside/backside stacked structure of FIG. 1, in which the frontside airgap 170 may be an augmented airgap. That is, the airgap 470 of FIG. 4 may be an augmented airgap. Then the metals 450 may be viewed as top signal metals of the first frontside signal layer 150. Also assume that the middle metal 450 is a first top signal metal. The augmented airgap 470 may comprise at least one side portion (in this instance, two side portions are shown) and an upper lateral portion. The at least one side portion may be formed on side surface(s) of the first top signal metal 450. The upper portion may be formed on an upper surface of the first top signal metal. Since there is another side portion, it may be said that the augmented airgap 470 comprises another side portion formed on another side surface of the first top signal metal 450.

One difference between device 300 and 400 is the following. As seen, there are multiple metals 450. If the metal on the left or the right of the middle metal 450 is assumed to a second top signal metal that is adjacent to the first top signal metal, then the lateral portion of the augmented airgap 470 may also be formed, at least partially, on an upper surface of the second top signal metal 450.

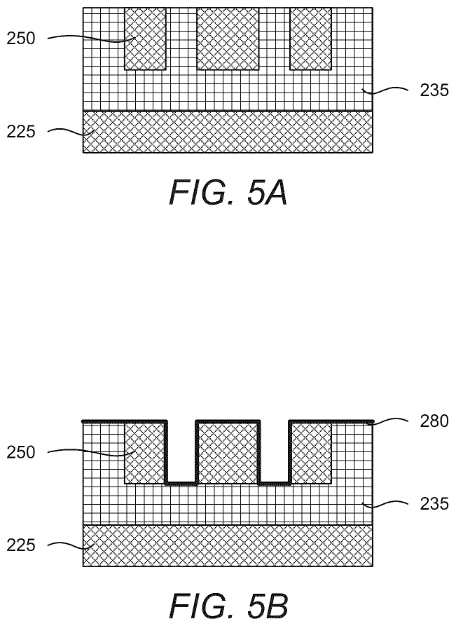

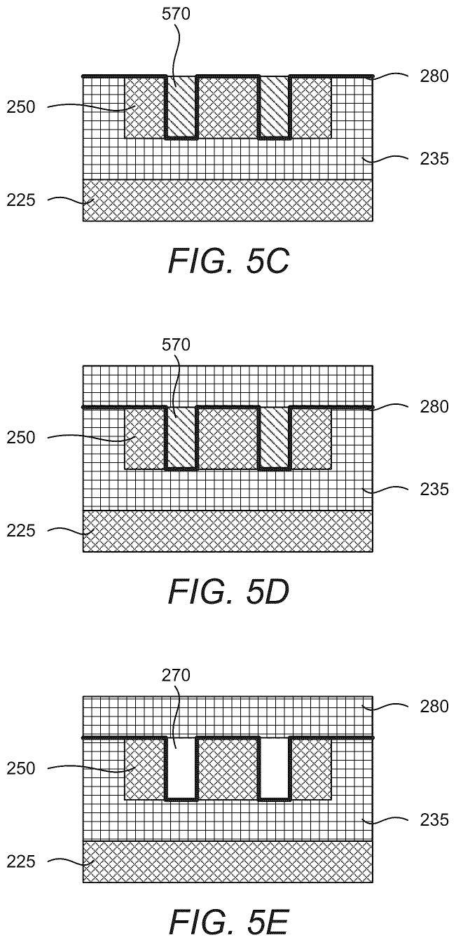

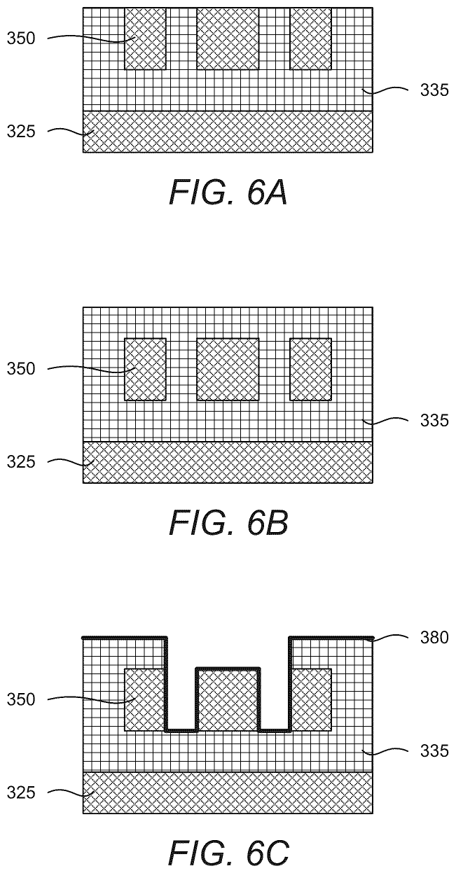

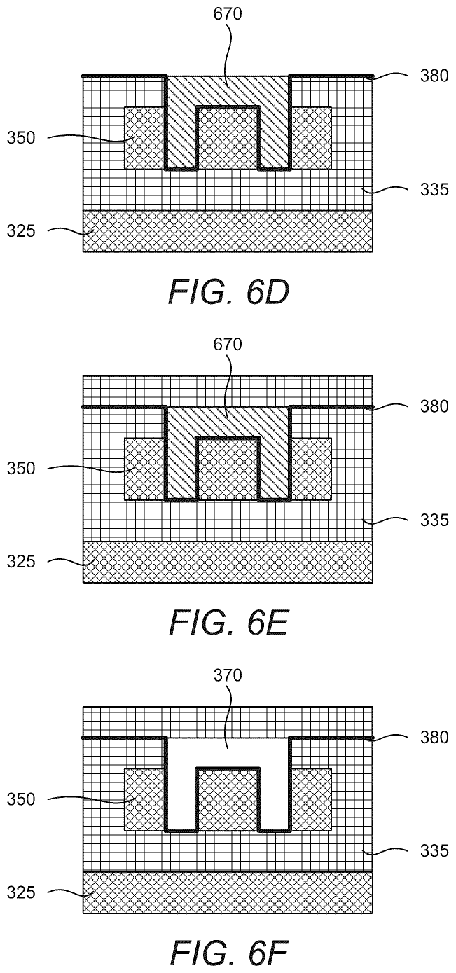

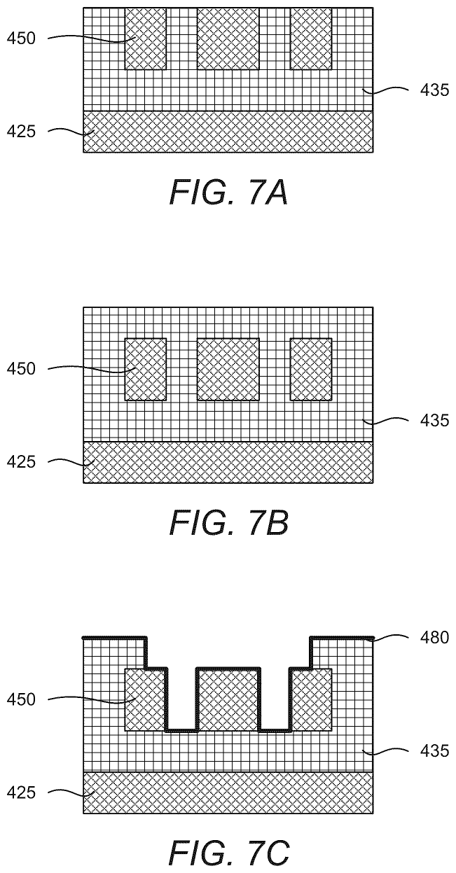

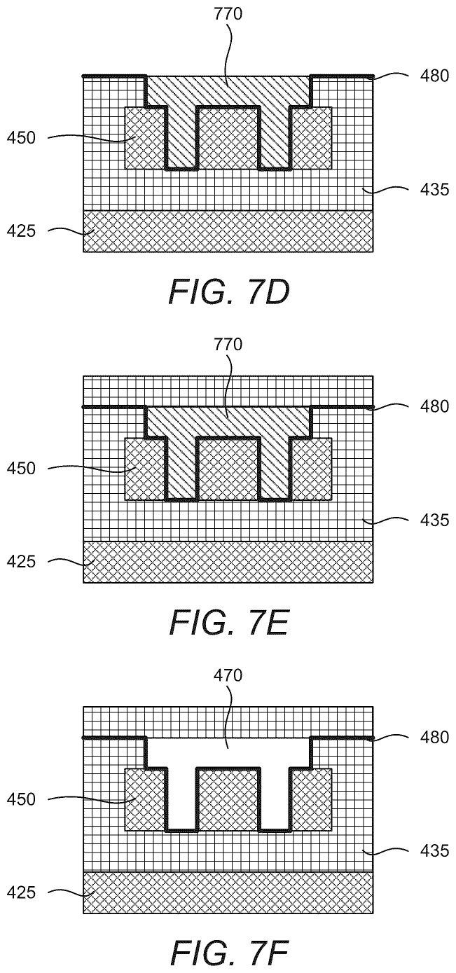

FIG. 5A-5E illustrate various stages of fabricating the metal layers of a device, such as the device 200 in accordance with one or more aspects of the disclosure. FIG. 5A illustrates a stage in which the dielectric 235, which is formed above a previous metal layer 225, may be polished (e.g., through chemical-mechanical polishing. The polishing may expose upper surfaces of the metals 250.

FIG. 5B illustrates a stage in which the dielectric 235 may be etched to expose upper surfaces of the metals 250. If the device corresponds to frontside or the backside signal layers 150, 155, then it may be said that the upper surfaces of the signal metals may be exposed. If the device corresponds to the frontside power layers 160, then it may be said that the upper surfaces of the power metals may be exposed. Note that holes that expose side and upper surfaces of the metals (signal metals, power metals) may be exposed. Thereafter, the protection layer 280 may be formed on the dielectric 235 and on the exposed side and upper surfaces of the metals (e.g., signal metals, power metals).

FIG. 5C illustrates a stage in which the holes may be filled with the sacrificial material 570 on the protection layer 280. Typical sacrificial material may include polymer related material. Such material can be deposited by, e.g., spin coater. It can fill completely up to the top of the metal or just fill to a height lower than the top of the metal.

FIG. 5D illustrates a stage in which the holes may be sealed with more material for the dielectric 235. That is, the dielectric 235 may be further built on the protection layer 280 and on the sacrificial material 570.

FIG. 5E illustrates a stage in which the sacrificial material 570 may be removed to form the airgaps 270. For example, the sacrificial material 570 may be thermally removed.

FIG. 6A-6F illustrate various stages of fabricating the metal layers of a device, such as the device 300 in accordance with one or more aspects of the disclosure.

FIG. 6A illustrates a stage in which the dielectric 335, which is formed above a previous metal layer 325, may be polished (e.g., through chemical-mechanical polishing. The polishing may expose upper surfaces of the metals 350.

FIG. 6B illustrates a stage in which the dielectric material may be further deposited on the polished upper surfaces of the dielectric 335 and the one or more top signal metals 350.

FIG. 6C illustrates a stage in which the dielectric 335 may be etched to expose upper surfaces of the top signal metals 350 including the first top signal metal. The etching may also form holes that expose the side surfaces of the one or more top signal metals 350. Then the protection layer 380 may be formed on the dielectric 335 and on the exposed side and upper surfaces of the metals 350.

FIG. 6D illustrates a stage in which the holes may be filled with the sacrificial material 670 on the protection layer 380.

FIG. 6E illustrates a stage in which the holes may be sealed with more material for the dielectric 335. That is, the dielectric 335 may be further built on the protection layer 380 and on the sacrificial material 670.

FIG. 6F illustrates a stage in which the sacrificial material 670 may be removed to form the augmented airgap 370. For example, the sacrificial material 670 may be thermally removed.

FIG. 7A-7F illustrate various stages of fabricating the metal layers of a device, such as the device 400 in accordance with one or more aspects of the disclosure.

FIG. 7A illustrates a stage in which the dielectric 435, which is formed above a previous metal layer 425, may be polished (e.g., through chemical-mechanical polishing. The polishing may expose upper surfaces of the metals 450.

FIG. 7B illustrates a stage in which the dielectric material may be further deposited on the polished upper surfaces of the dielectric 435 and the one or more top signal metals 450.

FIG. 7C illustrates a stage in which the dielectric 435 may be etched to expose upper surfaces of the top signal metals 450 including the first top signal metal. The etching may also form holes that expose the side surfaces of the one or more top signal metals 450. Then the protection layer 480 may be formed on the dielectric 435 and on the exposed side and upper surfaces of the metals 450.

FIG. 7D illustrates a stage in which the holes may be filled with the sacrificial material 770 on the protection layer 480.

FIG. 7E illustrates a stage in which the holes may be sealed with more material for the dielectric 435. That is, the dielectric 435 may be further built on the protection layer 480 and on the sacrificial material 770.

FIG. 7F illustrates a stage in which the sacrificial material 770 may be removed to form the augmented airgap 470. For example, the sacrificial material 770 may be thermally removed. Note that the augmented airgap 470 may be different from the augmented airgap 370. For example, upper lateral portion of the augmented airgap 470 may be formed, at least in part, on an upper surface of the second top signal metal 450 (e.g., left and/or right metal 450.

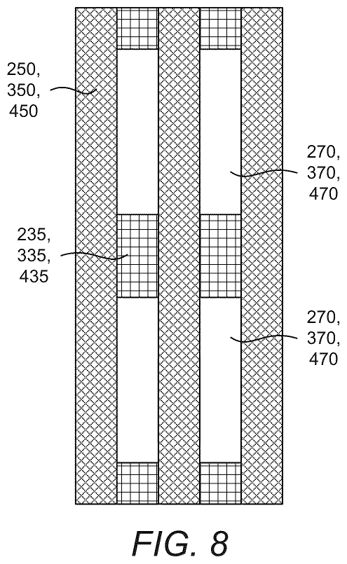

FIG. 8 illustrates a top view of a device with airgaps in stacked metal layers in accordance with one or more aspects of the present disclosure. Note that the airgaps 270, 370, 470 need not run the whole lengths of the metals 250, 350, 450. Indeed, the airgaps 270, 370, 470 may be spaced apart by the dielectrics 235, 335, 435 for mechanical reliability reasons.

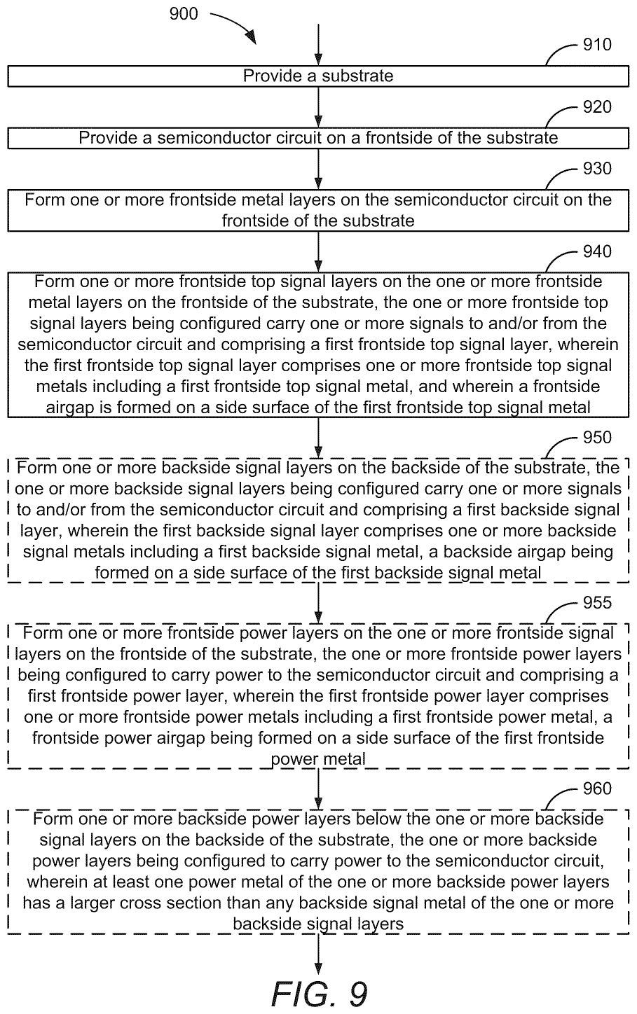

FIG. 9 illustrates a flow chart of an example method 900 of fabricating metal layers of devices with airgaps, such as devices 200, 300, 400 in accordance with one or more aspects of the disclosure.

In block 910, a substrate 110 may be provided.

In block 920, a semiconductor circuit 120 may be provided on a frontside of the substrate 110.

In block 930, one or more frontside metal layers—such as the frontside lower metal layers 130 and/or the frontside intermediate metal layers 140—may be formed on the semiconductor circuit 120 on the frontside of the substrate 110.

In block 940, one or more frontside signal layers 150 may be formed on the one or more frontside metal layers on the frontside of the substrate. The one or more frontside signal layers 150 may be configured to carry one or more signals to and/or from the semiconductor circuit 120.

The one or more frontside signal layers 150 may comprise a first frontside signal layer 150. The first frontside signal layer 150 may comprise one or more top signal metals (e.g., metals 250, 350, 450) including a first top signal metal. A frontside airgap 170 may be formed on a side surface of the first top signal metal 250, 350, 450.

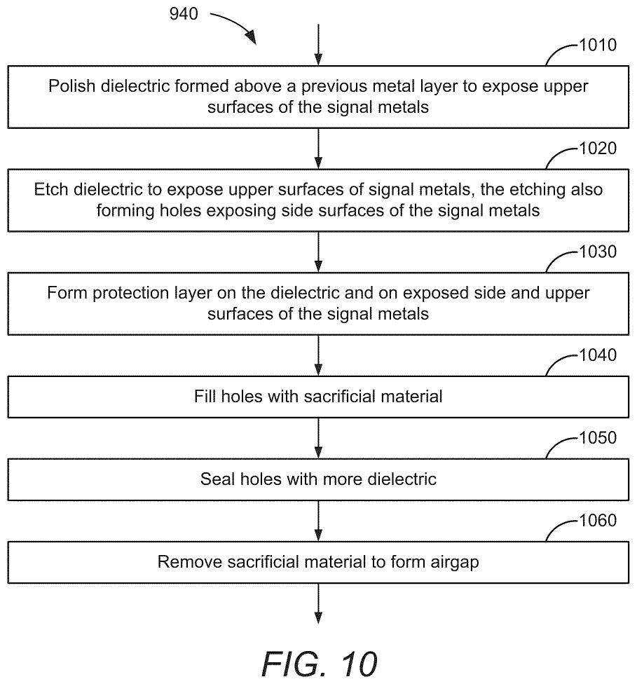

FIG. 10 illustrates a flowchart of an example process to implement block 940. In block 1010, a dielectric, which is formed above a previous metal layer, may be polished. The polishing may expose upper surfaces of the signal metals. Block 1010 may correspond to FIG. 5A.

In block 1020, the dielectric 235 may be etched to expose upper surfaces of the signal metals 250. The etching may also form holes exposing the side surfaces of the signal metals 250. Block 1020 may correspond to FIG. 5B.

In block 1030, protection layer 280 may be formed on the dielectric and on exposed side and upper surfaces of the signal metals. Block 1030 may also correspond to FIG. 5B.

In block 1040, the holes may be filled with the sacrificial material 570 on the protection layer 280. Block 1040 may correspond to FIG. 5C.

In block 1050, the holes may be sealed with more material for the dielectric. That is, the dielectric may be further built on the protection layer and on the sacrificial material 570. Block 1050 may correspond to FIG. 5D.

In block 1060, the sacrificial material 570 may be removed (e.g., thermally) to form the airgaps 270. Block 1060 may correspond to FIG. 5E.

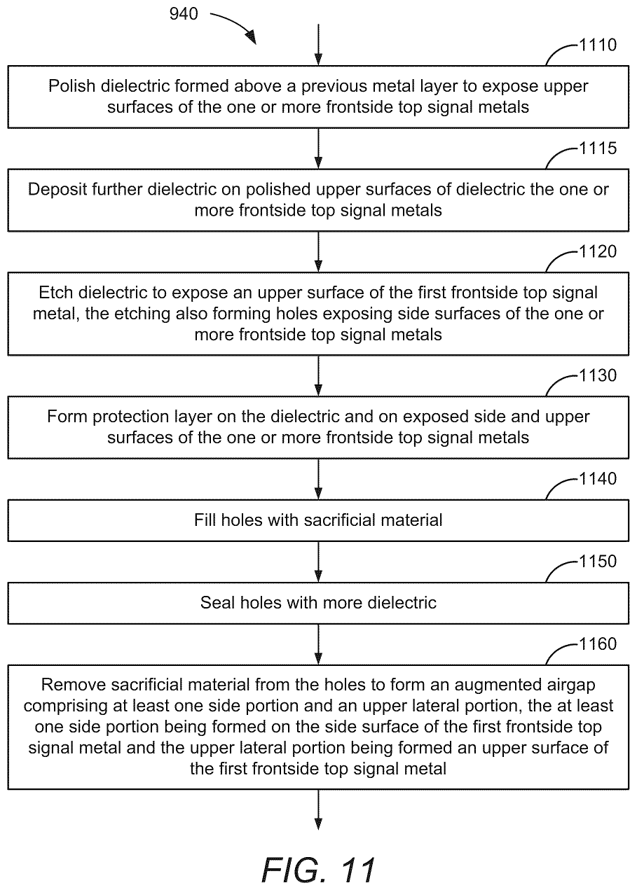

FIG. 11 illustrates a flowchart of another example process to implement block 940. In block 1110, a dielectric 335, 435, which is formed above a previous metal layer 325, 425, may be polished. The polishing may expose upper surfaces of the signal metals 350, 450. Block 1110 may correspond to FIG. 6A and/or FIG. 7A.

In block 1115, dielectric material may be further deposited on polished upper surfaces of the dielectric 335, 435 and the one or more top signal metals 350, 450. Block 1115 may correspond to FIG. 6B and/or FIG. 7B.

In block 1120, the dielectric may be etched to expose an upper surface of the first top signal metal 350, 450. The etching may also form holes exposing side surfaces of the one or more top signal metals 350, 450. Block 1120 may correspond to FIG. 6C and/or FIG. 7C.

In block 1130, a protection layer 380, 480 may be formed on the dielectric 335, 435 and on the exposed side and upper surfaces of the one or more top signal metals 350, 450. Block 1130 may also correspond to FIG. 6C and/or FIG. 7C.

In block 1140, the holes may be filled with a sacrificial material 670, 770. Block 1140 may correspond to FIG. 6D and/or FIG. 7D.

In block 1150, the holes may be filled sealed with more dielectric 335, 435. Block 1150 may correspond to FIG. 6E and/or FIG. 7E.

In block 1160, the sacrificial material 670, 770 may be removed from the holes to form an augmented airgap 370, 470. The augmented airgap 370, 470 may comprise at least one side portion and an upper lateral portion. The at least one side portion may be formed on the side surface of the first top signal metal 350, 450. The upper lateral portion may be formed an upper surface of the first top signal metal 350, 450. Block 1160 may correspond to FIG. 6F and/or FIG. 7F.

Referring back to FIG. 9, in block 950, one or more backside signal layers 155 may be formed on the backside of the substrate 110. The one or more backside signal layers 155 may be configured to carry one or more signals to and/or from the semiconductor circuit 120. The one or more backside signal layers 155 may comprise a first backside signal layer 155, which may comprise one or more backside signal metals including a first backside signal metal. A backside airgap 174 may be formed on a side surface of the first backside signal metal. Block 950 may be optional as indicated by the dashed box.

In block 955, one or more frontside power layers 160 may be formed on the one or more frontside signal layers 150 on the frontside of the substrate 110. The one or more frontside power layers 160 may be configured to carry power to the semiconductor circuit 120 and comprise a first frontside power layer 160, The first frontside power layer 160 may comprise one or more frontside power metals including a first frontside power metal. A frontside power airgap 172 may be formed on a side surface of the first frontside power metal. At least one power metal of the one or more frontside power layers 160 may have a larger cross section than any frontside signal metal of the one or more frontside signal layers 150.

In block 960, one or more backside power layers 165 may be formed below the one or more backside signal layers 155 on the backside of the substrate 110. The one or more backside power layers 165 may be configured to carry power to the semiconductor circuit 120. At least one power metal of the one or more backside power layers 165 may have a larger cross section than any backside signal metal of the one or more backside signal layers 155.

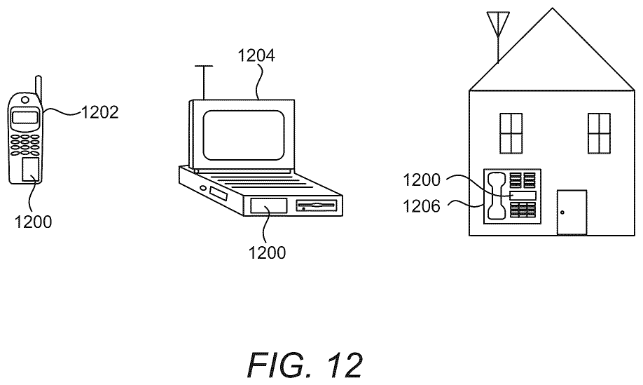

FIG. 12 illustrates various electronic devices 1200 that may be integrated with any of the aforementioned devices in accordance with various aspects of the disclosure. For example, a mobile phone device 1202, a laptop computer device 1204, and a fixed location terminal device 1206 may each be considered generally user equipment (UE) and may include one or more devices (e.g., devices 200, 300, 400) as described herein. The devices 1202, 1204, 1206 illustrated in FIG. 12 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A device comprising: a substrate; a semiconductor circuit on a frontside of the substrate; one or more frontside metal layers on the semiconductor circuit on the frontside of the substrate; and one or more frontside signal layers on the one or more frontside metal layers on the frontside of the substrate, the one or more frontside signal layers being configured to carry one or more signals to and/or from the semiconductor circuit and comprising a first frontside signal layer, wherein the first frontside signal layer comprises one or more top signal metals including a first top signal metal, and wherein a frontside airgap is formed on a side surface of the first top signal metal.

Clause 2: The device of clause 1, wherein the first top signal metal has a larger cross section than any metal of the frontside metal layers.

Clause 3: The device of any of clauses 1-2, wherein another frontside airgap is formed on another side surface of the first top signal metal.

Clause 4: The device of any of clauses 1-3, wherein the frontside airgap is an augmented airgap comprising at least one side portion and an upper lateral portion, the at least one side portion being formed on the side surface of the first top signal metal and the upper lateral portion being formed an upper surface of the first top signal metal.

Clause 5: The device of clause 4, wherein the augmented airgap further comprises another side portion formed on another side surface of the first top signal metal.

Clause 6: The device of any of clauses 4-5, wherein the one or more top signal metals also includes a second top signal metal adjacent to the first top signal metal, and wherein the upper lateral portion of the augmented airgap is formed, at least partially, on an upper surface of the second top signal metal.

Clause 7: The device of any of clauses 4-6, wherein the first frontside signal layer is an uppermost metal layer on the frontside of the substrate.

Clause 8: The device of any of clauses 4-7, further comprising: one or more backside signal layers on the backside of the substrate, the one or more backside signal layers being configured to carry one or more signals to and/or from the semiconductor circuit and comprising a first backside signal layer, wherein the first backside signal layer comprises one or more backside signal metals including a first backside signal metal, a backside airgap being formed on a side surface of the first backside signal metal.

Clause 9: The device of clause 8, wherein the backside airgap is a first backside airgap, wherein the one or more backside signal layers also includes a second backside signal layer immediately below or immediately above the first backside signal layer, and wherein a second backside airgap is formed on a side surface at least one signal metal of the second backside signal layer.

Clause 10: The device of any of clauses 8-9, further comprising: one or more backside power layers below the one or more backside signal layers on the backside of the substrate, the one or more backside power layers being configured to carry power to the semiconductor circuit, wherein at least one power metal of the one or more backside power layers has a larger cross section than any backside signal metal of the one or more backside signal layers.

Clause 11: The device of any of clauses 1-10, wherein the frontside airgap is a first frontside airgap, wherein the one or more frontside signal layers also includes a second frontside signal layer immediately below or immediately above the first frontside signal layer, and wherein a second frontside airgap is formed on a side surface at least one signal metal of the second frontside signal layer.

Clause 12: The device of any of clauses 1-11, further comprising: one or more frontside power layers on the one or more frontside signal layers on the frontside of the substrate, the one or more frontside power layers being configured to carry power to the semiconductor circuit and comprising a first frontside power layer, wherein the first frontside power layer comprises one or more frontside power metals including a first frontside power metal, a frontside power airgap being formed on a side surface of the first frontside power metal.

Clause 13: The device of clause 12, wherein the first frontside power metal has a larger cross section than any top signal metal of the one or more frontside signal layers.

Clause 14: The device of any of clauses 12-13, wherein the frontside power airgap is a first frontside power airgap, wherein the one or more frontside power layers also includes a second frontside power layer immediately below or immediately above the first frontside power layer, and wherein a second frontside power airgap is formed on a side surface at least one frontside power metal of the second frontside power layer.

Clause 15: The device of any of clauses 1-14, wherein the device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 16: A method of fabricating a device, the method comprising: providing a substrate; providing a semiconductor circuit on a frontside of the substrate; forming one or more frontside metal layers on the semiconductor circuit on the frontside of the substrate; and forming one or more frontside signal layers on the one or more frontside metal layers on the frontside of the substrate, the one or more frontside signal layers being configured to carry one or more signals to and/or from the semiconductor circuit and comprising a first frontside signal layer, wherein the first frontside signal layer comprises one or more top signal metals including a first top signal metal, and wherein a frontside airgap is formed on a side surface of the first top signal metal.

Clause 17: The method of clause 16, wherein the first top signal metal has a larger cross section than any metal of the frontside metal layers.

Clause 18: The method of any of clauses 16-17, wherein another frontside airgap is formed on another side surface of the first top signal metal.

Clause 19: The method of any of clauses 16-18, wherein forming the one or more frontside signal layers on the one or more frontside metal layers on the frontside of the substrate comprises: polishing dielectric formed above a previous metal layer to expose upper surfaces of the one or more top signal metals; further depositing dielectric on polished upper surfaces of the dielectric and the one or more top signal metals; etching the dielectric to expose an upper surface of the first top signal metal, the etching also forming holes exposing side surfaces of the one or more top signal metals; forming a protection layer on the dielectric and on the exposed side and upper surfaces of the one or more top signal metals; filling the holes with a sacrificial material; sealing the holes with more dielectric; and removing the sacrificial material from the holes to form an augmented airgap comprising at least one side portion and an upper lateral portion, the at least one side portion being formed on the side surface of the first top signal metal and the upper lateral portion being formed an upper surface of the first top signal metal.

Clause 20: The method of clause 19, wherein the augmented airgap further comprises another side portion formed on another side surface of the first top signal metal.

Clause 21: The method of any of clauses 19-20, wherein the one or more top signal metals also includes a second top signal metal adjacent to the first top signal metal, and wherein the upper lateral portion of the augmented airgap is formed, at least partially, on an upper surface of the second top signal metal.

Clause 22: The method of any of clauses 19-21, wherein the first frontside signal layer is an uppermost metal layer on the frontside of the substrate.

Clause 23: The method of any of clauses 19-22, further comprising forming one or more backside signal layers on the backside of the substrate, the one or more backside signal layers being configured to carry one or more signals to and/or from the semiconductor circuit and comprising a first backside signal layer, and wherein the first backside signal layer comprises one or more backside signal metals including a first backside signal metal, a backside airgap being formed on a side surface of the first backside signal metal.

Clause 24: The method of clause 23, wherein the backside airgap is a first backside airgap, wherein the one or more backside signal layers also includes a second backside signal layer immediately below or immediately above the first backside signal layer, and wherein a second backside airgap is formed on a side surface at least one signal metal of the second backside signal layer.

Clause 25: The method of any of clauses 23-24, further comprising: forming one or more backside power layers below the one or more backside signal layers on the backside of the substrate, the one or more backside power layers being configured to carry power to the semiconductor circuit, wherein at least one power metal of the one or more backside power layers has a larger cross section than any backside signal metal of the one or more backside signal layers.

Clause 26: The method of any of clauses 16-25, wherein the frontside airgap is a first frontside airgap, wherein the one or more frontside signal layers also includes a second frontside signal layer immediately below or immediately above the first frontside signal layer, and wherein a second frontside airgap is formed on a side surface at least one signal metal of the second frontside signal layer.

Clause 27: The method of any of clauses 16-26, further comprising: forming one or more frontside power layers on the one or more frontside signal layers on the frontside of the substrate, the one or more frontside power layers being configured to carry power to the semiconductor circuit and comprising a first frontside power layer, wherein the first frontside power layer comprises one or more frontside power metals including a first frontside power metal, a frontside power airgap being formed on a side surface of the first frontside power metal.

Clause 28: The method of clause 27, wherein the first frontside power metal has a larger cross section than any top signal metal of the one or more frontside signal layers.

Clause 29: The method of any of clauses 27-28, wherein the frontside power airgap is a first frontside power airgap, wherein the one or more frontside power layers also includes a second frontside power layer immediately below or immediately above the first frontside power layer, and wherein a second frontside power airgap is formed on a side surface at least one frontside power metal of the second frontside power layer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A device comprising:
a substrate;
a semiconductor circuit on a frontside of the substrate;
one or more frontside metal layers on the semiconductor circuit on the frontside of the substrate; and
one or more frontside signal layers on the one or more frontside metal layers on the frontside of the substrate, the one or more frontside signal layers being configured to carry one or more signals to and/or from the semiconductor circuit and comprising a first frontside signal layer,
wherein the first frontside signal layer comprises one or more top signal metals including a first top signal metal, and
wherein a frontside airgap is formed on a side surface of the first top signal metal.

2. The device of claim 1, wherein the first top signal metal has a larger cross section than any metal of the frontside metal layers.

3. The device of claim 1, wherein another frontside airgap is formed on another side surface of the first top signal metal.

4. The device of claim 1, wherein the frontside airgap is an augmented airgap comprising at least one side portion and an upper lateral portion, the at least one side portion being formed on the side surface of the first top signal metal and the upper lateral portion being formed an upper surface of the first top signal metal.

5. The device of claim 4, wherein the augmented airgap further comprises another side portion formed on another side surface of the first top signal metal.

6. The device of claim 4,
wherein the one or more top signal metals also includes a second top signal metal adjacent to the first top signal metal, and
wherein the upper lateral portion of the augmented airgap is formed, at least partially, on an upper surface of the second top signal metal.

7. The device of claim 4, wherein the first frontside signal layer is an uppermost metal layer on the frontside of the substrate.

8. The device of claim 4, further comprising:
one or more backside signal layers on the backside of the substrate, the one or more backside signal layers being configured to carry one or more signals to and/or from the semiconductor circuit and comprising a first backside signal layer,
wherein the first backside signal layer comprises one or more backside signal metals including a first backside signal metal, a backside airgap being formed on a side surface of the first backside signal metal.

9. The device of claim 8,
wherein the backside airgap is a first backside airgap,
wherein the one or more backside signal layers also includes a second backside signal layer immediately below or immediately above the first backside signal layer, and
wherein a second backside airgap is formed on a side surface at least one signal metal of the second backside signal layer.

10. The device of claim 8, further comprising:
one or more backside power layers below the one or more backside signal layers on the backside of the substrate, the one or more backside power layers being configured to carry power to the semiconductor circuit,
wherein at least one power metal of the one or more backside power layers has a larger cross section than any backside signal metal of the one or more backside signal layers.

11. The device of claim 1,
wherein the frontside airgap is a first frontside airgap,
wherein the one or more frontside signal layers also includes a second frontside signal layer immediately below or immediately above the first frontside signal layer, and
wherein a second frontside airgap is formed on a side surface at least one signal metal of the second frontside signal layer.

12. The device of claim 1, further comprising:
one or more frontside power layers on the one or more frontside signal layers on the frontside of the substrate, the one or more frontside power layers being configured to carry power to the semiconductor circuit and comprising a first frontside power layer,
wherein the first frontside power layer comprises one or more frontside power metals including a first frontside power metal, a frontside power airgap being formed on a side surface of the first frontside power metal.

13. The device of claim 12, wherein the first frontside power metal has a larger cross section than any top signal metal of the one or more frontside signal layers.

14. The device of claim 12,
wherein the frontside power airgap is a first frontside power airgap,
wherein the one or more frontside power layers also includes a second frontside power layer immediately below or immediately above the first frontside power layer, and
wherein a second frontside power airgap is formed on a side surface at least one frontside power metal of the second frontside power layer.

15. The device of claim 1, wherein the device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

16. A method of fabricating a device, the method comprising:
providing a substrate;
providing a semiconductor circuit on a frontside of the substrate;
forming one or more frontside metal layers on the semiconductor circuit on the frontside of the substrate; and
forming one or more frontside signal layers on the one or more frontside metal layers on the frontside of the substrate, the one or more frontside signal layers being configured to carry one or more signals to and/or from the semiconductor circuit and comprising a first frontside signal layer,
wherein the first frontside signal layer comprises one or more top signal metals including a first top signal metal, and
wherein a frontside airgap is formed on a side surface of the first top signal metal.

17. The method of claim 16, wherein the first top signal metal has a larger cross section than any metal of the frontside metal layers.

18. The method of claim 16, wherein another frontside airgap is formed on another side surface of the first top signal metal.

19. The method of claim 16, wherein forming the one or more frontside signal layers on the one or more frontside metal layers on the frontside of the substrate comprises:
polishing dielectric formed above a previous metal layer to expose upper surfaces of the one or more top signal metals;
further depositing dielectric on polished upper surfaces of the dielectric and the one or more top signal metals;
etching the dielectric to expose an upper surface of the first top signal metal, the etching also forming holes exposing side surfaces of the one or more top signal metals;
forming a protection layer on the dielectric and on the exposed side and upper surfaces of the one or more top signal metals;
filling the holes with a sacrificial material;
sealing the holes with more dielectric; and
removing the sacrificial material from the holes to form an augmented airgap comprising at least one side portion and an upper lateral portion, the at least one side portion being formed on the side surface of the first top signal metal and the upper lateral portion being formed an upper surface of the first top signal metal.

20. The method of claim 19, wherein the augmented airgap further comprises another side portion formed on another side surface of the first top signal metal.

21. The method of claim 19,
wherein the one or more top signal metals also includes a second top signal metal adjacent to the first top signal metal, and
wherein the upper lateral portion of the augmented airgap is formed, at least partially, on an upper surface of the second top signal metal.

22. The method of claim 19, wherein the first frontside signal layer is an uppermost metal layer on the frontside of the substrate.

23. The method of claim 19, further comprising:
forming one or more backside signal layers on the backside of the substrate, the one or more backside signal layers being configured to carry one or more signals to and/or from the semiconductor circuit and comprising a first backside signal layer, and
wherein the first backside signal layer comprises one or more backside signal metals including a first backside signal metal, a backside airgap being formed on a side surface of the first backside signal metal.

24. The method of claim 23,
wherein the backside airgap is a first backside airgap,
wherein the one or more backside signal layers also includes a second backside signal layer immediately below or immediately above the first backside signal layer, and
wherein a second backside airgap is formed on a side surface at least one signal metal of the second backside signal layer.

25. The method of claim 23, further comprising:
forming one or more backside power layers below the one or more backside signal layers on the backside of the substrate, the one or more backside power layers being configured to carry power to the semiconductor circuit,
wherein at least one power metal of the one or more backside power layers has a larger cross section than any backside signal metal of the one or more backside signal layers.

26. The method of claim 16,
wherein the frontside airgap is a first frontside airgap,
wherein the one or more frontside signal layers also includes a second frontside signal layer immediately below or immediately above the first frontside signal layer, and
wherein a second frontside airgap is formed on a side surface at least one signal metal of the second frontside signal layer.

27. The method of claim 16, further comprising:
forming one or more frontside power layers on the one or more frontside signal layers on the frontside of the substrate, the one or more frontside power layers being configured to carry power to the semiconductor circuit and comprising a first frontside power layer,
wherein the first frontside power layer comprises one or more frontside power metals including a first frontside power metal, a frontside power airgap being formed on a side surface of the first frontside power metal.

28. The method of claim 27, wherein the first frontside power metal has a larger cross section than any top signal metal of the one or more frontside signal layers.

29. The method of claim 27,
wherein the frontside power airgap is a first frontside power airgap,
wherein the one or more frontside power layers also includes a second frontside power layer immediately below or immediately above the first frontside power layer, and
wherein a second frontside power airgap is formed on a side surface at least one frontside power metal of the second frontside power layer.
